(19) United States
(12) Patent Application Publication
(10) Pub. No.: US 2011/0227601 A1
(43) Pub. Date: Sep. 22, 2011

(54) TEST METHOD OF SEMICONDUCTOR INTEGRATED CIRCUIT AND TEST SYSTEM, AND SEMICONDUCTOR INTEGRATED CIRCUIT

(75) Inventors: Toru Hashimoto, Kanagawa-ken (JP); Tatsuhiro Gake, Kanagawa-ken (JP)

(73) Assignee: KABUSHIKI KAISHA TOSHIBA, Tokyo (JP)

(21) Appl. No.: 12/960,859

(22) Filed: Dec. 6, 2010

(30) Foreign Application Priority Data
Mar. 19, 2010 (JP) 2010-63597

(51) Int. Cl. G01R 31/26; H01L 27/06

(52) U.S. Cl. 324/762.02; 257/48; 257/E27.016

(57) ABSTRACT

A test system tests a semiconductor integrated circuit. The semiconductor integrated circuit including a signal terminal to and from a signal is input and output, an RF circuit which processes an RF signal, and a capacitor which is connected between the signal terminal and the RF circuit. The test system has a probe which applies a test signal to the signal terminal and a tester which tests the RF circuit. Before the RF circuit is tested, with the probe and the signal terminal in contact with each other, the tester determines whether the probe and the signal terminal are in a conductive state.

### CROSS-REFERENCE TO RELATED APPLICATION

This application is based upon and claims the benefit of priority from the prior Japanese Patent Application No.2010-63597, filed on Mar. 19, 2010, the entire contents of which are incorporated herein by reference.

### BACKGROUND

1. Field

Embodiments described herein relate generally to a method and a system for testing a semiconductor integrated circuit that tests a contact between a test probe and a pad, and a semiconductor integrated circuit.

2. Background Art

In the conventional art, in a die sorting (D/S) process of semiconductor integrated circuits (ICs) for radio communication, a contact test of a probe needs to be executed before a test. That is, it is verified whether a probe is in contact with a pad of a semiconductor integrated circuit.

In general, a semiconductor integrated circuit incorporates a capacitor between a pad to which a radio frequency (RF) signal is input and an RF circuit which processes the RF signal, to cut a direct-current component DC. For this reason, a tester has a problem in that it cannot execute a test for contact between a pad and a probe based on a direct-current component DC, in a state where the semiconductor integrated circuit does not boot up logically.

In the conventional art, there is a technology in which a high frequency signal is applied to a semiconductor chip from a control line and a contact between a pad and a probe is tested on the basis of a signal output from the semiconductor chip via the control signal.

However, in the conventional art, the semiconductor chip needs to be boot up logically. That is, in the conventional art, the contact test may not be executed in a state where the semiconductor chip does not boot up logically.

### BRIEF DESCRIPTION OF THE DRAWINGS

FIG. 1 is a top view showing an example of the configuration of a semiconductor device according to a first embodiment;

FIG. 2 is a block diagram showing an example of the configuration of a test system that tests the semiconductor integrated circuit according to the first embodiment;

FIG. 3 is a block diagram showing an example of the configuration of a test system that tests a semiconductor integrated circuit according to a modification of the first embodiment;

FIG. 4 is a block diagram showing an example of the configuration of a test system that tests the semiconductor integrated circuit according to the second embodiment;

FIG. 5 is a block diagram showing an example of the configuration of a test system that tests the semiconductor integrated circuit according to a modification of the second embodiment;

FIG. 6 is a block diagram showing an example of the configuration of a test system that tests the semiconductor integrated circuit according to another modification of the second embodiment;

FIG. 7 is a block diagram showing an example of the configuration of a test system that tests the semiconductor integrated circuit according to the third embodiment;

FIG. 8 is a block diagram showing an example of the configuration of a test system that tests a semiconductor integrated circuit according to a modification of the third embodiment;

FIG. 9 is a block diagram showing an example of the configuration of a test system that tests the semiconductor integrated circuit according to the fourth embodiment; and

FIG. 10 is a block diagram showing another example of the configuration of the test system that tests the semiconductor integrated circuit.

### DETAILED DESCRIPTION

A test system according to an embodiment, tests a semiconductor integrated circuit. The semiconductor integrated circuit including a signal terminal to and from a signal is input and output, an RF circuit which processes an RF signal, and a capacitor which is connected between the signal terminal and the RF circuit. The test system has a probe which applies a test signal to the signal terminal and a tester which tests the RF circuit. Before the RF circuit is tested, with the probe and the signal terminal in contact with each other, the tester determines whether the probe and the signal terminal are in a conductive state.

Hereafter, embodiments of the present invention will be described more specifically with reference to the drawings.

[First Embodiment]

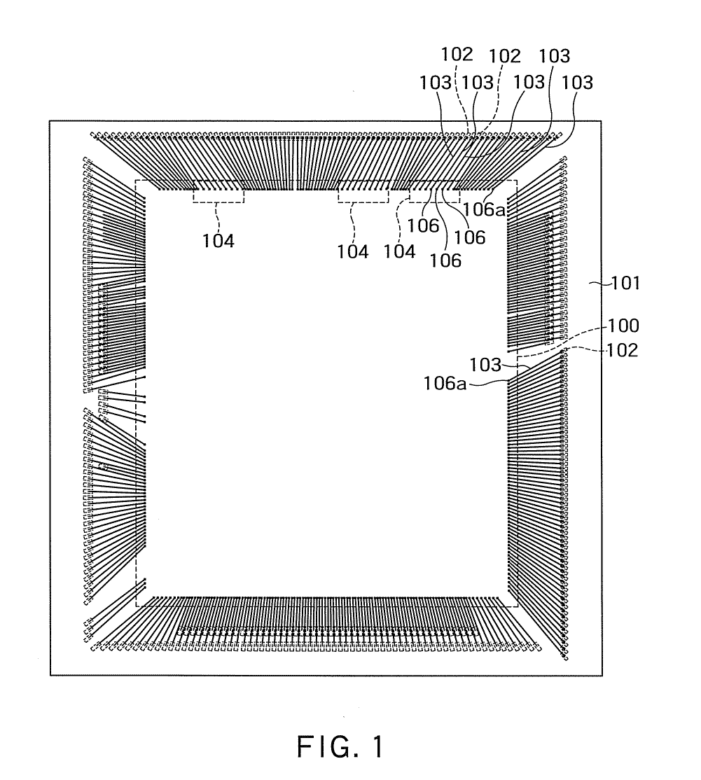

FIG. 1 is a top view showing an example of the configuration of a semiconductor device according to a first embodiment.

As shown in FIG. 1, a semiconductor device (semiconductor chip) includes a package substrate 101, a semiconductor integrated circuit (IC) 100 that is provided on the package substrate 101, bonding pads 102 that are provided on the package substrate 101, pads (terminals) 106 and 106a that are provided on the semiconductor integrated circuit 100, and a bonding wire 103 that electrically connects the bonding pads 102 with the pads 106 and 106a.

In this case, each pad 106 in a region 104 receives an RF signal and a test signal or is connected to a ground. Each pad 106a outside the region 104 receives a signal for controlling the semiconductor integrated circuit 100 or is connected to a power supply or a ground.

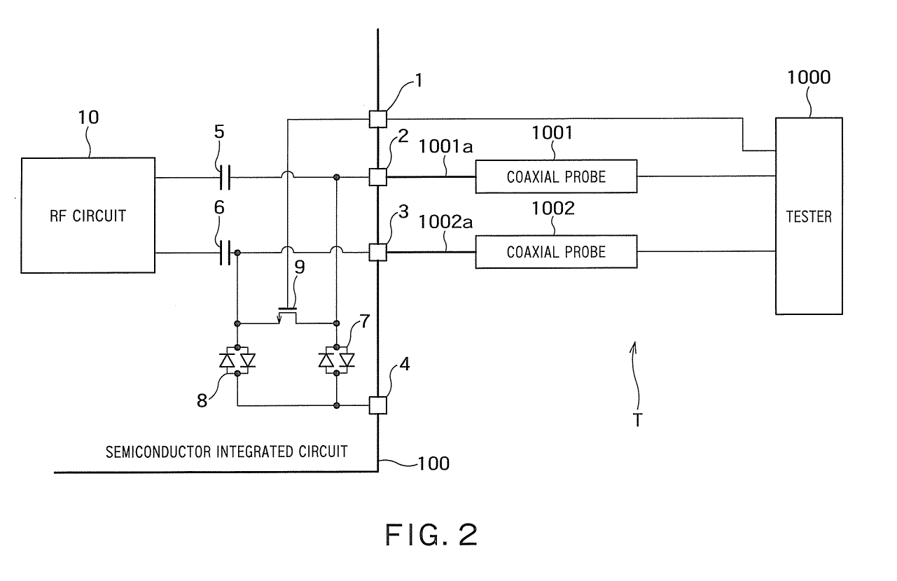

FIG. 2 is a block diagram showing an example of the configuration of a test system that tests the semiconductor integrated circuit according to the first embodiment.

First, as shown in FIG. 2, the semiconductor integrated circuit 100 includes a control terminal (pad) 1, a first signal terminal (pad) 2, a second signal terminal (pad) 3, a ground terminal (pad) 4, a first capacitor 5, a second capacitor 6, a first protective element 7, a second protective element 8, a MOS transistor 9, and an RF circuit 10. The terminals (pads) 1 to 4 shown in FIG. 2 correspond to either the pads 106 or the pads 106a shown in FIG. 1.

The first signal terminal 2 receives or outputs the RF signal during a normal operation. The first signal terminal 2 receives a test signal during a test operation, as will be described below.

The second signal terminal 3 receives or outputs the RF signal during the normal operation. The second signal terminal 3 receives the test signal during the test operation, as will be described below.

The RF circuit 10 processes the RF signals that are input through the first and the second signal terminals 2 and 3. The RF circuit 10 includes a circuit that is used in a transceiver, such as a low noise amplifier (LNA) and a driver.

The first capacitor 5 is connected between the first signal terminal 2 and the RF circuit 10. The first capacitor 5 cuts a direct-current component of the signal that is input through the first signal terminal 2.

The second capacitor 6 is connected between the second signal terminal 3 and the RF circuit 10. The second capacitor 6 cuts a direct-current component of the signal that is input through the second signal terminal 3.

The control terminal 1 is configured to receive a control voltage from a tester 1000.

In the MOS transistor 9, an end is connected to the first signal terminal 2, the other end is connected to the second signal terminal 3, and a gate is connected to the control terminal 1. The MOS transistor 9 is controlled according to a voltage applied to the control terminal 1.

Even when the control terminal 1 is the power supply pad, the MOS transistor 9 is controlled according to the voltage applied to the control terminal 1.

The ground terminal 4 is grounded through the bonding wire 102 and the bonding pad 103 shown in FIG. 1.

The first protective element 7 is connected between the ground terminal 4 and the first signal terminal 2. The first protective element 7 includes two diodes in which anodes and cathodes are connected.

The second protective element 8 is connected between the ground terminal 4 and the second signal terminal 3. The second protective element 8 includes two diodes in which a cathode of one diode and an anode of the other diode are connected.

Meanwhile, as shown in FIG. 2, a test system T includes a tester 1000, a first probe 1001a, a first coaxial probe 1001, a second probe 1002a, and a second coaxial probe 1002.

The first probe 1001a is connected to the tester 1000 through the first coaxial probe 1001. The first probe 1001a is connected to the first signal terminal 2 at the time of a test. A test signal that is generated by the tester 1000 is applied to the first signal terminal 2 through the first probe 1001a. A signal such as a reflection wave that is output from the semiconductor integrated circuit 100 is input to the tester 1000 through the first signal terminal 2 and the first probe 1001a.

The second probe 1002a is connected to the tester 1000 through the second coaxial probe 1002. The second probe 1002a is connected to the second signal terminal 3 at the time of a test. A test signal that is generated by the tester 1000 is applied to the second signal terminal 3 through the second probe 1002a. A signal such as a reflection wave that is output from the semiconductor integrated circuit 100 is input to the tester 1000 through the second signal terminal 3 and the second probe 1002a.

The first and second probes 1001a and 1002a are central conductors of, for example, the coaxial probes 1001 and 1002.

In order to secure an RF characteristic in a die sorter, the first and second coaxial probes are used for the first and second signal terminals 2 and 3 receiving and outputting the RF signals.

The tester 1000 generates various test signals and outputs the test signals to the semiconductor integrated circuit 100 via the first and second probes 1001a and 1002a. The tester 1000 analyzes the signals (current and voltage) that are input from the semiconductor integrated circuit 100 via the first and second probes 1001a and 1002a, to test the RF circuit 10.

That is, the test system T applies various test signals to the semiconductor integrated circuit 100 and executes various tests on the semiconductor integrated circuit 100.

Next, an example of the operation of the test system T with the above configuration performing a test for an electrical contact between the first and second signal terminals 2 and 3, and the first and second probes 1001a and 1002a before the RF circuit 10 is tested will be described.

First, before the RF circuit 10 is tested, the first probe 1001a and the first signal terminal 2 are made to be in contact with each other and the second probe 1002a and the second signal terminal 3 are made to be in contact with each other.

In this state, the tester 1000 applies a control voltage of a predetermined level to the control terminal 1. The MOS transistor 9 is turned on according to the control voltage applied to the control terminal 1.

The control terminal 1 may be a power supply pad to which a ground voltage is applied before the RF circuit 10 is tested and to which a power supply voltage is applied during a normal operation of the RF circuit 10. In this case, a voltage of a predetermined level (for example, ground voltage) is applied before the RF circuit 10 is tested, and the MOS transistor 9 is turned on in response to the ground voltage. In the example shown in FIG. 2, the MOS transistor 9 is an nMOS transistor. However, when the control terminal 1 is a power supply pad, the MOS transistor 9 may be a pMOS transistor.

Next, the tester 1000 measures a direct current that flows between the first probe 1001a and the second probe 1002a through the MOS transistor 9.

The tester 1000 determines whether the first probe 1001a and the first signal terminal 2 are in a conductive state and the second probe 1002a and the second signal terminal 3 are in a conductive state, on the basis of the direct current. For example, when the direct current is a defined value or less, the tester 1000 determines that at least one of a contact between the first probe 1001a and the first signal terminal 2 and a contact between the second probe 1002a and the second signal terminal 3 is failed.

During the contact test, the RF circuit 10 is not included in a path of the direct current. That is, during the contact test, since a signal is not input to or output from the RF circuit 10, the RF circuit does not need to boot up logically.

During the normal operation of the RF circuit 10, when the RF circuit 10 is tested, a voltage of a predetermined level (for example, ground voltage) is applied to the control terminal 1 and the MOS transistor 9 is turned off in response to the voltage. As a result, the RF signal is input to or output from the RF circuit 10 and the predetermined test signal is input from the tester 1000 to the RF circuit 10.

When the control terminal 1 is the power supply pad, a power supply voltage is applied during the normal operation of the RF circuit 10 (including the test operation of the RF circuit 10). For this reason, the MOS transistor 9 (pMOS transistor in this case, as described above) is turned off.

Next, an example of the configuration in which an influence on a signal from the parasitic capacity of the MOS transistor 9 is reduced will be described.

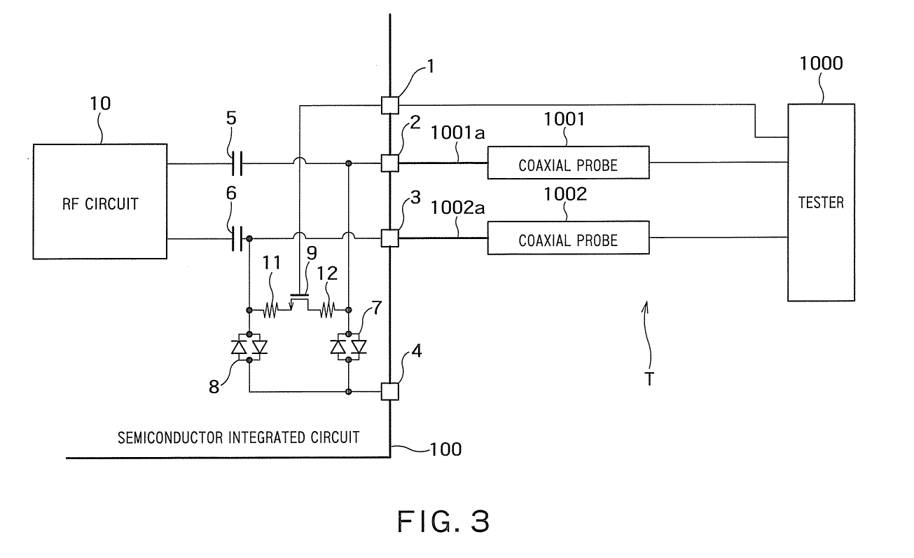

FIG. 3 is a block diagram showing an example of the configuration of a test system that tests a semiconductor integrated circuit according to a modification of the first embodiment.

As shown in FIG. 3, the semiconductor integrated circuit 100 further includes a first resistor 11 that is connected between one end (source) of the MOS transistor 9 and the first capacitor 5, and a second resistor 12 that is connected between the other end (drain) of the MOS transistor 9 and the second capacitor 6. The other parts of the configuration of the semiconductor integrated circuit 100 are the same as those of the configuration of FIG. 2.

As such, the first and second resistors 11 and 12 that have high resistance values are additionally connected to both ends of the MOS transistor 9. Thereby, during the operation of the RF circuit 10, when the MOS transistor 9 is turned off, but the parasitic capacity of the MOS transistor 9 is not observed from the first and second signal terminals 2 and 3 and the RF circuit 10.

With this configuration, the influence on the signal from the parasitic capacity of the MOS transistor 9 can be reduced.

As such, according to the test method and test system of the semiconductor integrated circuit in this embodiment, the contact between the test probes and the pads can be easily tested.

[Second Embodiment]

In the second embodiment, an example of the configuration where a semiconductor integrated circuit has two MOS transistors functioning as a differential switch will be described.

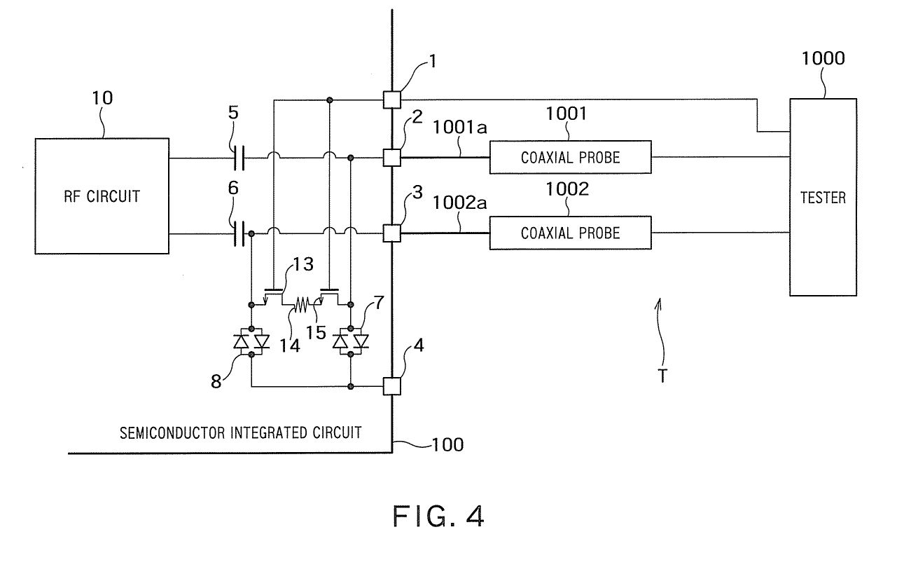

FIG. 4 is a block diagram showing an example of the configuration of a test system that tests the semiconductor integrated circuit according to the second embodiment. In FIG. 4, like reference numerals of FIG. 2 denote like components of the first embodiment. The semiconductor integrated circuit 100 shown in FIG. 4 is also applied to the semiconductor device (semiconductor chip) shown in FIG. 1.

As shown in FIG. 4, the semiconductor integrated circuit 100 includes a control terminal (pad) 1, a first signal terminal (pad) 2, a second signal terminal (pad) 3, a ground terminal (pad) 4, a first capacitor 5, a second capacitor 6, a first protective element 7, a second protective element 8, an RF circuit 10, a first MOS transistor 13, a resistor 14, and a second MOS transistor 15.

One end of the resistor 14 is connected to the first signal terminal 2 through the first MOS transistor 13 and the other end thereof is connected to the second signal terminal 3. A resistance value of the resistor 14 is set so as to realize impedance matching with a transmission path including the first probe 1001a and the second probe 1002a linked to the tester 1000.

One end (source) of the first MOS transistor 13 is connected to the first signal terminal 2, the other end (drain) thereof is connected to one end of the resistor 14, and a gate thereof is connected to the control terminal 1. The first MOS transistor 13 is controlled according to a control voltage applied to the control terminal 1.

One end (source) of the second MOS transistor 15 is connected to the second signal terminal 3, the other end (drain) thereof is connected to other end of the resistor 14, and a gate thereof is connected to the control terminal 1. The second MOS transistor 15 is controlled according to a control voltage applied to the control terminal 1.

As such, the semiconductor integrated circuit 100 according to the second embodiment is different from the semiconductor integrated circuit 100 according to the first embodiment in that the first and second MOS transistors 13 and 15 and the resistor 14 connected in series are provided, instead of the MOS transistor 9. The other parts of the configuration are the same as those of the configuration of the first embodiment.

Next, an example of the operation of when the test system T having the above configuration tests electrical contact of the first and second signal terminals 2 and 3 and the first and second probes 1001a and 1002a before the RF circuit 10 is tested will be described.

First, before the RF circuit 10 is tested, the first probe 1001a and the first signal terminal 2 are made to be in contact with each other and the second probe 1002a and the second signal terminal 3 are made to be in contact with each other.

In this state, the tester 1000 applies a control voltage of a predetermined level to the control terminal 1. Thereby, the first and second MOS transistors 13 and 15 are turned on in response to the control voltage applied to the control terminal 1.

When the control terminal 1 is a power supply pad, a voltage of a predetermined level (for example, ground voltage) is applied before the RF circuit 10 is tested and the first and second MOS transistors 13 and 15 are turned on in response to the ground voltage. In the example shown in FIG. 4, the first and second MOS transistors 13 and 15 are nMOS transistors. However, when the control terminal 1 is the power supply pad, the first and second MOS transistors 13 and 15 may be pMOS transistors.

Next, the tester 1000 measures a reflection wave (reflection coefficient) from the semiconductor integrated circuit 100, when alternating-current signals (differential signals) are output from the first probe 1001a and the second probe 1002a.

The tester 1000 determines whether the first probe 1001a and the first signal terminal 2 are in a conductive state and the second probe 1002a and the second signal terminal 3 are in a conductive state, on the basis of the reflection wave (reflection coefficient).

For example, when the reflection wave (reflection coefficient) is equal to or more than a defined value (for example, total reflection), the tester 1000 determines that at least one of a contact between the first probe 1001a and the first signal terminal 2 and a contact between the second probe 1002a and the second signal terminal 3 is failed.

Meanwhile, when the reflection wave (reflection coefficient) is less than the defined value (for example, non-reflection), the tester 1000 determines that there is no contact failure.

During the contact test, the RF circuit does not need to boot up logically.

During the normal operation of the RF circuit 10, when the RF circuit 10 is tested, a voltage of a predetermined level (for example, ground voltage) is applied to the control terminal 1, and the first and second MOS transistors 13 and 15 are turned off in response to the voltage. Thereby, the RF signal is input to or output from the RF circuit 10 and the predetermined test signal is input from the tester 1000 to the RF circuit 10.

When the control terminal 1 is the power supply pad, a power supply voltage is applied during the normal operation (including a test operation of the RF circuit 10) of the RF circuit 10. For this reason, the first and second MOS transistors 13 and 15 (pMOS transistors in this case, as described above) are turned off.

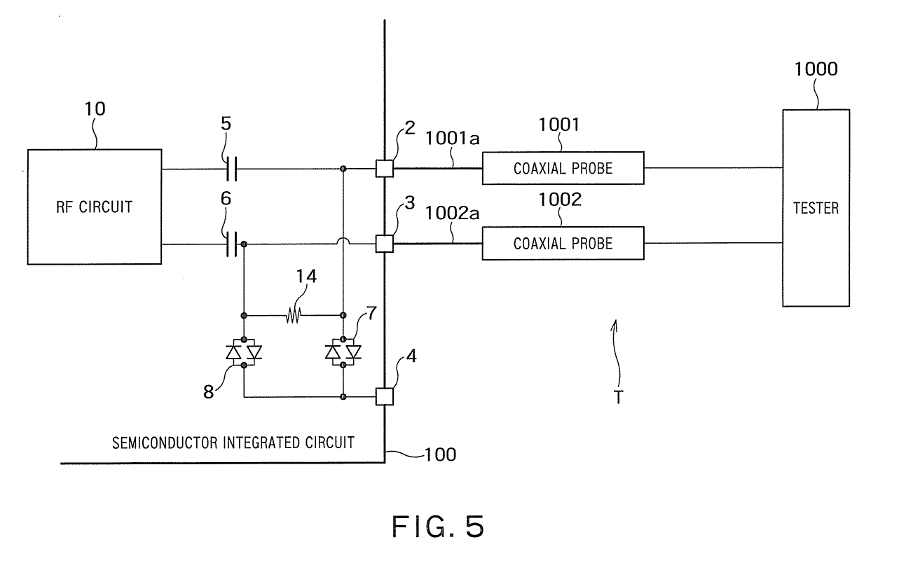

In the second embodiment, even though the first and second MOS transistors 13 and 15 are not provided, the contact test of the probes can be executed. FIG. 5 is a block diagram showing an example of the configuration of a test system that tests the semiconductor integrated circuit according to a modification of the second embodiment.

As shown in FIG. 5, in the semiconductor integrated circuit 100, the first and second MOS transistors 13 and 15 and the control terminal 1 for controlling the first and second MOS transistors 13 and 15 are not provided. The other parts of the configuration of the semiconductor integrated circuit 100 are the same as those of the configuration of FIG. 4.

Even in the semiconductor integrated circuit 100 shown in FIG. 5, as described above, the tester 1000 measures a reflection wave (reflection coefficient) from the semiconductor integrated circuit 100, when alternating-current signals (differential signals) are output from the first probe 1001a and the second probe 1002a. The tester 1000 can determine whether the first probe 1001a and the first signal terminal 2 are in a conductive state and the second probe 1002a and the second signal terminal 3 are in a conductive state, on the basis of the reflection wave (reflection coefficient).

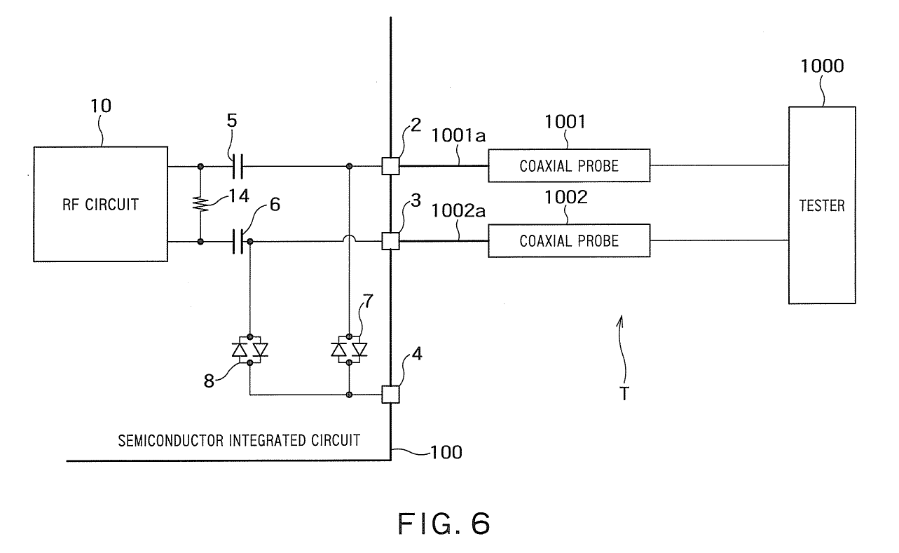

FIG. 6 is a block diagram showing an example of the configuration of a test system that tests the semiconductor integrated circuit according to another modification of the second embodiment.

As shown in FIG. 6, in the semiconductor integrated circuit 100, the first and second MOS transistors 13 and 15 and the control terminal 1 for controlling the first and second MOS transistors 13 and 15 are not provided. The resistor 14 is connected between the other end of the first capacitor 5 and the other end of the second capacitor 6. The other parts of the configuration of the semiconductor integrated circuit 100 are the same as those of the configuration of FIG. 4.

Even in the semiconductor integrated circuit 100 shown in FIG. 6, as described above, the tester 1000 measures a reflection wave (reflection coefficient) from the semiconductor integrated circuit 100, when alternating-current signals (differential signals) are output from the first probe 1001a and the second probe 1002a. The tester 1000 can determine whether the first probe 1001a and the first signal terminal 2 are in a conductive state and the second probe 1002a and the second signal terminal 3 are in a conductive state, on the basis of the reflection wave (reflection coefficient).

As such, according to the test method of the semiconductor integrated circuit and the test system in this embodiment, the contacts of the test probes and the pads can be easily tested.

[Third Embodiment]

In the third embodiment, an example of the configuration where a semiconductor integrated circuit has a single-phase circuit will be described.

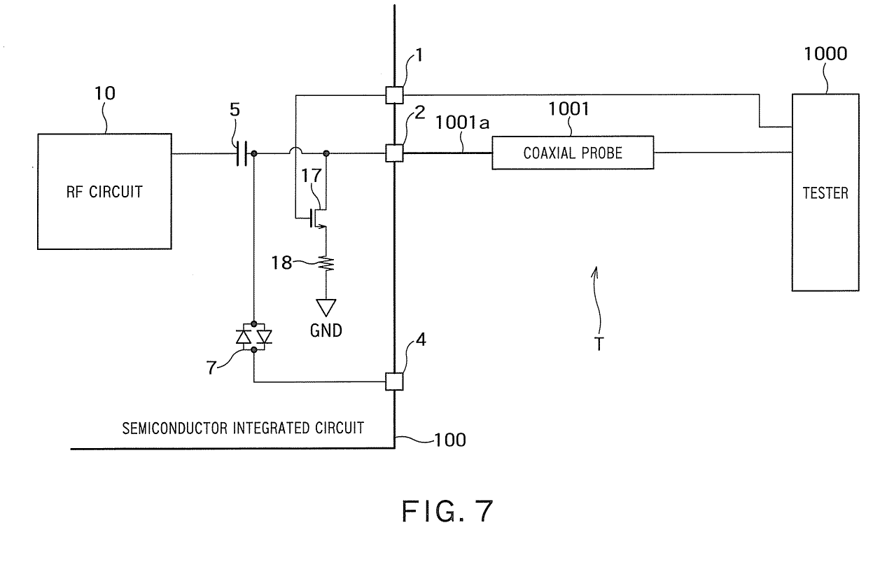

FIG. 7 is a block diagram showing an example of the configuration of a test system that tests the semiconductor integrated circuit according to the third embodiment. In FIG. 7, the same reference numerals as those of FIG. 4 denote the same components as those of the second embodiment. The semiconductor integrated circuit 100 shown in FIG. 7 is also applied to the semiconductor device (semiconductor chip) shown in FIG. 1.

As shown in FIG. 7, the semiconductor integrated circuit 100 includes a control terminal (pad) 1, a first signal terminal (pad) 2, a ground terminal (pad) 4, a first capacitor 5, a first protective element 7, an RF circuit 10, a MOS transistor 17, and a resistor 18.

One end of the resistor 18 is connected to the first signal terminal 2 through the MOS transistor 17 and the other end thereof is connected to a ground (connected to the other connection terminal not shown in the drawings). A resistance value of the resistor 18 is set so as to realize impedance matching with a transmission path including the first probe 1001a linked to the tester 1000.

One end (drain) of the MOS transistor 17 is connected to the first signal terminal 2, the other end (source) thereof is connected to one end of the resistor 18, and a gate thereof is connected to the control terminal 1. The MOS transistor 17 is controlled according to a control voltage applied to the control terminal 1.

As such, the semiconductor integrated circuit 100 according to the fourth embodiment includes the single-phase circuit. That is, the RF circuit 10 processes an RF signal of a single phase. The other parts of the configuration are the same as those of the configuration of the second embodiment.

Next, an example of the operation when the test system T having the above configuration tests an electrical contact between the first signal terminal 2 and the first probe 1001a before the RF circuit 10 is tested will be described.

First, before the RF circuit 10 is tested, the first probe 1001a and the first signal terminal 2 are in contact with each other.

In this state, the tester 1000 applies a control voltage of a predetermined level to the control terminal 1. Thereby, the MOS transistor 17 is turned on according to the control voltage applied to the control terminal 1.

When the control terminal 1 is a power supply pad, a voltage of a predetermined level (for example, ground voltage) is applied before the RF circuit 10 is tested and the MOS transistor 17 is turned on in response to the ground voltage. In the example shown in FIG. 7, the MOS transistor 17 is an nMOS transistor. However, when the control terminal 1 is the power supply pad, the MOS transistor 17 may be a pMOS transistor.

Next, the tester 1000 measures a reflection wave (reflection coefficient) from the semiconductor integrated circuit 100, when an alternating-current signal is output from the first probe 1001a.

The tester 1000 determines whether the first probe 1001a and the first signal terminal 2 are in a conductive state, on the basis of the reflection wave (reflection coefficient).

For example, when the reflection wave (reflection coefficient) is equal to or more than a defined value (for example, total reflection), the tester 1000 determines that a contact between the first probe 1001a and the first signal terminal 2 is failed.

Meanwhile, when the reflection wave (reflection coefficient) is less than the regular value (for example, non-reflection), the tester 1000 determines that there is no contact failure.

During the contact test, the RF circuit does not need to boot up logically.

During the normal operation of the RF circuit 10, when the RF circuit 10 is tested, a voltage of a predetermined level (for example, ground voltage) is applied to the control terminal 1, and the MOS transistor 17 is turned off according to the voltage. Thereby, the RF signal is input to or output from the RF circuit 10 and the predetermined test signal is input from the tester 1000 to the RF circuit 10.

When the control terminal 1 is the power supply pad, a power supply voltage is applied during the normal operation of the RF circuit 10 (including a test operation of the RF circuit 10). For this reason, the MOS transistor 17 (pMOS transistor in this case, as described above) is turned off.

In the semiconductor integrated circuit 100 according to the third embodiment, as in the modification of the second embodiment shown in FIG. 5, the control terminal 1 and the MOS transistor 17 may not be provided.

Even in this case, the tester 1000 can measure a reflection wave (reflection coefficient) from the semiconductor integrated circuit 100, when an alternating-current signal is output from the first probe 1001a. The tester 1000 can determine whether the first probe 1001a and the first signal terminal 2 are in a conductive state, on the basis of the reflection wave (reflection coefficient).

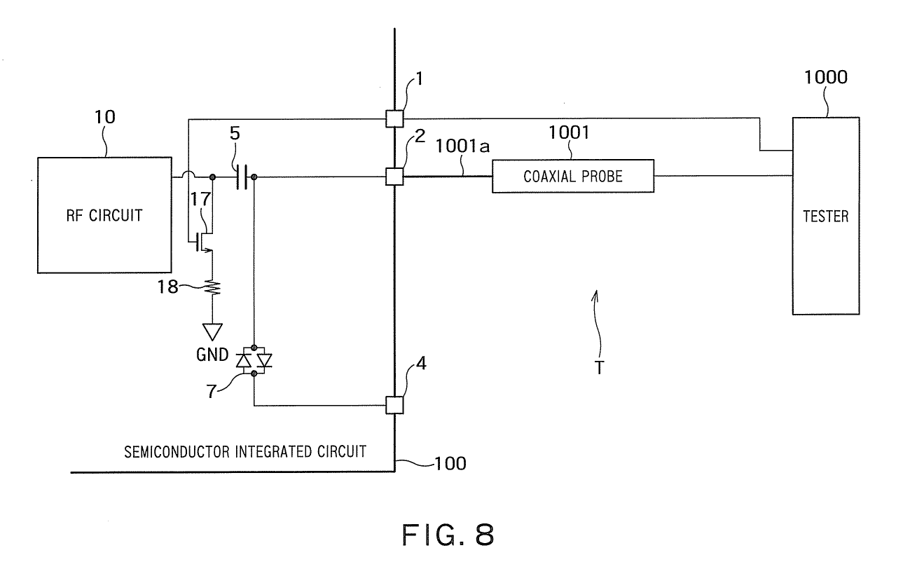

FIG. 8 is a block diagram showing an example of the configuration of a test system that tests a semiconductor integrated circuit according to a modification of the third embodiment.

As shown in FIG. 8, the semiconductor integrated circuit 100 includes a control terminal (pad) 1, a first signal terminal (pad) 2, a ground terminal (pad) 4, a first capacitor 5, a first protective element 7, a MOS transistor 17, an RF circuit 10, and a resistor 18.

One end of the resistor 18 is connected to the other end of the first capacitor 5 through the MOS transistor 17 and the other end thereof is connected to a ground (connected to the other connection terminal not shown in the drawings). A resistance value of the resistor 18 is set so as to realize impedance matching with a transmission path including the first probe 1001a linked to the tester 1000.

One end (drain) of the MOS transistor 17 is connected to the other end of the first capacitor 5, the other end thereof (source) is connected to one end of the resistor 14, and a gate thereof is connected to the control terminal 1. The MOS transistor 17 is controlled according to a control voltage applied to the control terminal 1.

The other parts of the configuration of the semiconductor integrated circuit 100 are the same as those of the configuration of FIG. 7.

Even in the semiconductor integrated circuit 100 shown in FIG. 8, as described above, the tester 1000 measures a reflection wave (reflection coefficient) from the semiconductor integrated circuit 100, when an alternating-current signal is output from the first probe 1001a. The tester 1000 can determine whether the first probe 1001a and the first signal terminal 2 are in a conductive state, on the basis of the reflection wave (reflection coefficient).

As such, according to the test method of the semiconductor integrated circuit and the test system in this embodiment, the contacts of the test probes and the pads can be easily tested.

[Fourth Embodiment]

In the fourth embodiment, calibration of probes of a test system will be described.

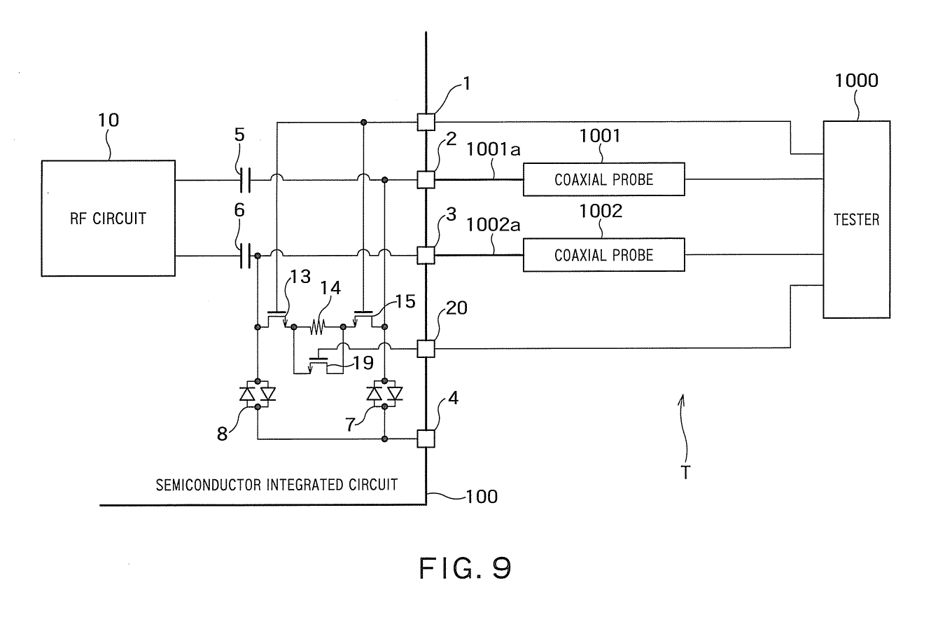

FIG. 9 is a block diagram showing an example of the configuration of a test system that tests the semiconductor integrated circuit according to the fourth embodiment. In FIG. 9, the same reference numerals as those of FIG. 4 denote the same components as those of the second embodiment. The semiconductor integrated circuit 100 shown in FIG. 9 is also applied to the semiconductor device (semiconductor chip) shown in FIG. 1.

As shown in FIG. 9, the semiconductor integrated circuit 100 further includes a calibration terminal 20 and a third MOS transistor 19, as compared with the configuration shown in FIG. 4. The other parts of the configuration of the semiconductor integrated circuit 100 are the same as those of the configuration of FIG. 4.

The calibration terminal 20 is configured such that a calibration control signal is applied from the tester 1000.

One end (source) of the third MOS transistor 19 is connected to one end of the resistor 14, the other end (drain) thereof is connected to the other end of the resistor 14, and a gate thereof is connected to the calibration terminal 20. The third MOS transistor 19 is controlled according to a voltage applied to the calibration terminal 20.

Next, an example of the operation of when the test system T executes the calibration of the probes before the RF circuit 10 is tested will be described.

First, the tester 1000 applies a control voltage of a predetermined level (for example, ground voltage) to the control terminal 1. Thereby, the first and second MOS transistors 13 and 15 are turned off according to the control voltage applied to the control terminal 1 (open state).

Next, the tester 1000 applies a control voltage of a predetermined level (for example, power supply voltage) to the control terminal 1 and applies a calibration control signal of a predetermined level (for example, power supply voltage) to the calibration terminal 20. Thereby, the first and second MOS transistors 13 and 15 are turned on according to the control voltage applied to the control terminal 1 and the first to third MOS transistors 13, 15, and 19 are turned on according to the calibration control signal applied to the calibration terminal 20 (short state).

Next, the tester 1000 applies a voltage of a predetermined level to the control terminal 1 and the calibration terminal 20.

Thereby, the first and second MOS transistors 13 and 15 are turned on and the third MOS transistor 19 is turned off. That is, the resistor 14 is observed (load state).

The tester 1000 executes the calibration of the first and second probes 1001a and 1002a in the open state, the short state, and the load state. Thereby, the tester 1000 can improve measurement precision based on the first and second probes.

Next, an example of the operation of when the test system T having the above configuration tests electric contacts of the first and second signal terminals 2 and 3 and the first and second probes 1001a and 1002a before the RF circuit 10 is tested will be described.

First, before the RF circuit 10 is tested, the first probe 1001a and the first signal terminal 2 are connected to each other and the second probe 1002a and the second signal terminal 3 are connected to each other.

In this state, the tester 1000 applies a voltage of a predetermined level to the control terminal 1 and the calibration terminal 20. Thereby, the first and second MOS transistors 13 and 15 are turned on and the third MOS transistor 19 is turned off. That is, the resistor 14 is observed. The following operation is the same as the operation of the second embodiment.

As such, according to the test method and test system of the semiconductor integrated circuit in this embodiment, the contacts of the probes for the test and the pads can be easily tested while the calibration is executed.

This embodiment is not applied limitatively to the die sorting process described above. The above-described embodiments may be applied to a contact test of balls (terminals) of a ball grid array (BGA) and probes (sockets) of a probe card, in an F/T process.

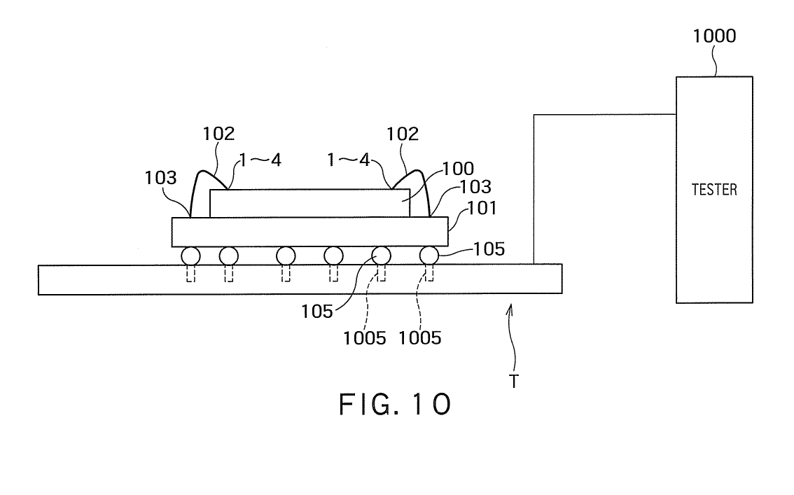

FIG. 10 is a block diagram showing another example of the configuration of the test system that tests the semiconductor integrated circuit. In FIG. 10, the same reference numerals as those of FIG. 1 denote the same components as those of the first embodiment.

As shown in FIG. 10, the test system T may test contacts of balls (terminals) 105 of a ball grid array (BGA) of the semiconductor device (semiconductor chip) and probes (sockets) 1005 of a probe card 1004 of the test system T, before the RF circuit 10 is tested. In this case, the semiconductor integrated circuit 100 has the same circuit configuration as those of the embodiments described above. The balls 105 correspond to the control terminal, the signal terminal, and the calibration terminal described above.

[Fifth Embodiment]

In the fifth embodiment, cleaning of probes of the test system will be described. In the following description, the configuration of FIG. 10 described above is used as an example. However, the configurations of FIGS. 1 to 9 may be used. That is, the probes 1005 of FIG. 10 correspond to the first and second probes 1001a and 1002a of FIGS. 1 to 9 and the balls 105 of FIG. 10 correspond to the first and second signal terminals 2 and 3 of FIGS. 1 to 9.

By the contact test or the RF test described in the embodiments, for example, solder, dust, and dirt are attached to the probes 1005 of the probe card 1004 of the test system T. If the contact test or the RF test is executed for each wafer; the solder, the dust, and the dirt are attached to the probes 1005. For this reason, direct-current resistance of a measurement system increases and a direct current decreases. Therefore, regular cleaning of the probes 1005 needs to be executed.

In this embodiment, the tester 1000 shown in FIG. 10 notifies a user of information indicating that cleaning (for example, removing the solder, the dust, and the dirt) needs to be executed on the probes 1005 or automatically cleans the probes 1005 (for example, removes the solder, the dust, and the dirt), on the basis of the result obtained by testing a conductive state of the probes 1005 and the balls 105.

For example, when a direct current between the probes 1005 and the balls 105 is less than a defined current value or when high frequency gain is less than a defined value, the tester 1000 executes the notification or the automatic cleaning.

If the user cleans the probes 1005 according to the notification or the tester automatically cleans the probes 1005, the contacts of the probes for the test and the pads can be appropriately tested.

This embodiment is not limited to the probe card and may be applied to a socket probe for a package test.

As such, according to this embodiment, the contacts of the test probes and the pads can be appropriately tested.

In the embodiments described above, the semiconductor integrated circuit includes the protective element. However, in this embodiment, the same effect can be obtained even though the protective element is not provided in the semiconductor integrated circuit.

In the embodiments described above, the semiconductor integrated circuit does not need to boot up logically during the contact test. However, in this embodiment, the same effect can be obtained even though the semiconductor integrated circuit boots up logically.

In the embodiments described above, the MOS transistor is used. However, the pMOS transistor or the nMOS transistor may be selected according to the necessity, for example, the polarity of the circuit.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A test system that tests a semiconductor integrated circuit, the semiconductor integrated circuit including a signal terminal to and from a signal is input and output, an RF circuit which processes an RF signal, and a capacitor which is connected between the signal terminal and the RF circuit, the test system comprising:
a probe which applies a test signal to the signal terminal; and
a tester which tests the RF circuit,
wherein, before the RF circuit is tested, with the probe and the signal terminal in contact with each other, the tester determines whether the probe and the signal terminal are in a conductive state.

2. The test system according to claim 1, wherein the semiconductor integrated circuit including a first signal terminal to and from which a signal is input and output, a second signal terminal to and from which a signal is input and output, an RF circuit which processes an RF signal, a first capacitor which is connected between the first signal terminal and the RF circuit, a second capacitor which is connected between the second signal terminal and the RF circuit, a control terminal, and a MOS transistor in which a first end is connected to the first signal terminal and a second end is connected to the second signal terminal and which is controlled according to a voltage applied to the control terminal, and
the test system comprising:
a first probe which applies a test signal to the first signal terminal;
a second probe which applies a test signal to the second signal terminal; and
a tester which tests the RF circuit,
wherein, before the RF circuit is tested, with the first probe and the first signal terminal made to be in contact with each other and the second probe and the second signal terminal are made to be in contact with each other, the MOS transistor is turned on according to the control voltage applied to the control terminal, and the tester determines whether the first probe and the first signal terminal are in a conductive state and the second probe and the second signal terminal are in a conductive state, on the basis of a direct current flowing between the first probe and the second probe through the MOS transistor.

3. The test system according to claim 2, wherein the semiconductor integrated circuit further includes a first resistor that is connected between the first end of the MOS transistor and the first capacitor, and a second resistor that is connected between the second end of the MOS transistor and the second capacitor.

4. The test system according to claim 2, wherein, during the normal operation of the RF circuit, the MOS transistor is turned off in response to a control voltage applied to the control terminal.

5. The test system according to claim 2, wherein the control terminal is configured to receive a control voltage from the tester.

6. The test system according to claim 2, wherein the control terminal is a power supply pad to which a ground voltage is applied before the RF circuit is tested and to which a power supply voltage is applied during a normal operation of the RF circuit.

7. The test system according to claim 1, wherein the tester notifies a user of information indicating that cleaning needs to be executed on the probes or automatically cleans the probe on the basis of a result obtained by testing a conductive state of the probe and the signal terminal.

8. The test system according to claim 1, wherein the semiconductor integrated circuit including a first signal terminal to and from which a signal is input and output, a second signal terminal to and from which a signal is input and output, an RF circuit which processes an RF signal, a first capacitor which is connected between the first signal terminal and the RF circuit, a second capacitor which is connected between the second signal terminal and the RF circuit, and a resistor in which a first end is connected to the first signal terminal and a second end is connected to the second signal terminal, and
the test system comprising:
a first probe which applies a test signal to the first signal terminal;
a second probe which applies a test signal to the second signal terminal; and
a tester which tests the RF circuit,
wherein, before the RF circuit is tested, with the first probe and the first signal terminal made to be in contact with each other and the second probe and the second signal terminal are made to be in contact with each other, and the tester determines whether the first probe and the first signal terminal are in a conductive state and the second probe and the second signal terminal are in a conductive state, on the basis of a reflection wave from the semiconductor integrated circuit, when alternating-current signals are output from the first probe and the second probe.

9. The test system according to claim 8, wherein the semiconductor integrated circuit further includes a control terminal, a first MOS transistor in which a first end is connected to the first signal terminal and a second end is connected to the first end of the resistor and which is controlled according to a control voltage applied to the control terminal, and a second MOS transistor in which a first end is connected to the second signal terminal and a second end is connected to the second end of the resistor and which is controlled according to a control voltage applied to the control terminal, and
wherein, before the RF circuit is tested, with the first probe and the first signal terminal made to be in contact with each other and the second probe and the second signal terminal are made to be in contact with each other, the first and second MOS transistors are turned on according to the control voltage applied to the control terminal.

10. The test system according to claim 8, wherein the resistor has a resistance value being set so as to realize impedance matching with a transmission path including the first probe and the second probe linked to the tester.

11. The test system according to claim 1, wherein the semiconductor integrated circuit including a first signal terminal to and from which a signal is input and output, an RF circuit which processes an RF signal, a first capacitor which is connected between the first signal terminal and the RF circuit, a ground terminal, and a resistor in which a first end is connected to the first signal terminal and a second end is connected to the ground terminal, and
the test system comprising:
a first probe which applies a test signal to the first signal terminal; and
a tester which tests the RF circuit,
wherein, before the RF circuit is tested, with the first probe and the first signal terminal made to be in contact with each other, and the tester determines whether the first probe and the first signal terminal are in a conductive state, on the basis of a reflection wave from the semiconductor integrated circuit, when an alternating-current signal is output from the first probe.

12. The test system according to claim 11, wherein, during the normal operation of the RF circuit, the first and second MOS transistors are turned off in response to a control voltage applied to the control terminal.

13. A test method that tests a semiconductor integrated circuit, the semiconductor integrated circuit including a signal terminal to and from a signal is input and output, an RF circuit which processes an RF signal, and a capacitor which is connected between the signal terminal and the RF circuit, the test method comprising:
determining whether the probe and the signal terminal are in a conductive state, before the RF circuit is tested, with the probe and the signal terminal in contact with each other.

14. The test method according to claim 13, wherein the semiconductor integrated circuit including a first signal terminal to and from which a signal is input and output, a second signal terminal to and from which a signal is input and output, an RF circuit which processes an RF signal, a first capacitor which is connected between the first signal terminal and the RF circuit, a second capacitor which is connected between the second signal terminal and the RF circuit, a control terminal, and a MOS transistor in which a first end is connected to the first signal terminal and a second end is connected to the second signal terminal and which is controlled according to a voltage applied to the control terminal, and
the test method comprising:
turning on the MOS transistor according to the control voltage applied to the control terminal, and
determining whether the first probe and the first signal terminal are in a conductive state and the second probe and the second signal terminal are in a conductive state, on the basis of a direct current flowing between the first probe and the second probe through the MOS transistor, before the RF circuit is tested, with the first probe and the first signal terminal made to be in contact with each other and the second probe and the second signal terminal are made to be in contact with each other.

15. The test method according to claim 13, wherein the semiconductor integrated circuit including a first signal terminal to and from which a signal is input and output, a second signal terminal to and from which a signal is input and output, an RF circuit which processes an RF signal, a first capacitor which is connected between the first signal terminal and the RF circuit, a second capacitor which is connected between the second signal terminal and the RF circuit, and a resistor in which a first end is connected to the first signal terminal and a second end is connected to the second signal terminal, and
the test system comprising:
determining whether the first probe and the first signal terminal are in a conductive state and the second probe and the second signal terminal are in a conductive state, on the basis of a reflection wave from the semiconductor integrated circuit, when alternating-current signals are output from the first probe and the second probe, before the RF circuit is tested, with the first probe and the first signal terminal made to be in contact with each other and the second probe and the second signal terminal are made to be in contact with each other.

16. The test method according to claim 13, wherein the semiconductor integrated circuit including a first signal terminal to and from which a signal is input and output, an RF circuit which processes an RF signal, a first capacitor which is connected between the first signal terminal and the RF circuit, a ground terminal, and a resistor in which a first end is connected to the first signal terminal and a second end is connected to the ground terminal, and
the test method comprising:
determining whether the first probe and the first signal terminal are in a conductive state, on the basis of a reflection wave from the semiconductor integrated circuit, when an alternating-current signal is output from the first probe, before the RF circuit is tested, with the first probe and the first signal terminal made to be in contact with each other.

17. A semiconductor integrated circuit, comprising:
a signal terminal to and from which a signal is input and output;
an RF circuit which processes an RF signal; and
a capacitor which is connected between the signal terminal and the RF circuit.

18. The semiconductor integrated circuit according to claim 17,
wherein the signal terminal includes a first signal terminal to and from which a signal is input and output and a second signal terminal to and from which a signal is input and output,
the capacitor includes a first capacitor which is connected between the first signal terminal and the RF circuit and a second capacitor which is connected between the second signal terminal and the RF circuit, and
the semiconductor integrated circuit further comprises a control terminal, and a MOS transistor in which a first end is connected to the first signal terminal and a second end is connected to the second signal terminal and which is controlled according to a voltage applied to the control terminal.

19. The semiconductor integrated circuit according to claim 17,
wherein the signal terminal includes a first signal terminal to and from which a signal is input and output and a second signal terminal to and from which a signal is input and output,
the capacitor includes a first capacitor which is connected between the first signal terminal and the RF circuit and a second capacitor which is connected between the second signal terminal and the RF circuit, and
the semiconductor integrated circuit further comprises a resistor in which a first end is connected to the first signal terminal and a second end is connected to the second signal terminal.

20. The semiconductor integrated circuit according to claim 17,
wherein the signal terminal includes a first signal terminal to and from which a signal is input and output,
the capacitor includes a first capacitor which is connected between the first signal terminal and the RF circuit, and
the semiconductor integrated circuit further comprises a resistor in which a first end is connected to the first signal terminal and a second end is connected to a ground.
